(19) United States
(12) Patent Application Publication
(10) Pub. No.: US 2026/0006896 A1
(43) Pub. Date: Jan. 1, 2026

(54) SOLID PHASE EPITAXY OF AMORPHOUS SEMICONDUCTOR OVER A CRYSTALLINE SUBSTRATE

(71) Applicant: TEXAS INSTRUMENTS INCORPORATED, Dallas, TX (US)

(72) Inventors: Haowen Bu, Wylie, TX (US); Umamaheswari Aghoram, Richardson, TX (US); Jonathan Lewis, Rowlett, TX (US); Xiangyu Zhu, Garland, TX (US); Majid Movahed Mansoori, Richardson, TX (US)

(21) Appl. No.: 18/758,852

(22) Filed: Jun. 28, 2024

(51) Int. Cl. H01L 27/06; H01L 21/02; H01L 21/225; H01L 29/94

(52) U.S. Cl. CPC H10D 84/811; H01L 21/02592; H01L 21/02667; H01L 21/2253; H10D 1/665

(57) ABSTRACT

A semiconductor device comprises a semiconductor substrate, a first crystalline silicon layer over the semiconductor substrate, an electronic component extending into the first crystalline silicon layer, a second crystalline silicon layer over the electronic component and the first crystalline silicon layer, and a layer of distributed silicon oxide inclusions between the first crystalline silicon layer and the second crystalline silicon layer.

### FIELD OF THE DISCLOSURE

Disclosed implementations relate generally to the field of integrated circuits (ICs) and IC fabrication.

### BACKGROUND

Epitaxy is used in semiconductor fabrication to create a suitable crystalline foundation layer on which to build a semiconductor device, to deposit a crystalline film with engineered electrical properties, and/or to alter mechanical attributes of an underlayer in a way that improves its electrical conductivity. In some instances, an epitaxial layer can be doped during deposition by adding impurities to the source gas in order to obtain desired electrical properties of the epitaxial layer.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

In one example, a method of fabricating an IC device is disclosed. The method may comprise, among others, forming a circuit component extending into a semiconductor substrate; depositing a silicon layer over the circuit component and the semiconductor substrate; implanting group IV implant species into the silicon layer; and heating the silicon layer, thereby forming a crystalline silicon layer over the circuit component.

In one example, a method is disclosed which may comprise, among others, depositing a silicon layer over a silicon crystal lattice; and implanting silicon ions into the silicon layer and the silicon crystal lattice, wherein the silicon layer crystalizes by solid phase epitaxy to extend the silicon crystal lattice.

In one example, a semiconductor device is disclosed which may comprise, among others, a semiconductor substrate; a first crystalline silicon layer over the semiconductor substrate; an electronic component extending into the first crystalline silicon layer; a second crystalline silicon layer over the electronic component and the first crystalline silicon layer; and a layer of distributed silicon oxide inclusions between the first crystalline silicon layer and the second crystalline silicon layer.

In one example, a method is disclosed which may comprise, among others, depositing a semiconductor layer over a semiconductor crystal lattice having an oxide layer thereover; and implanting group IV ions into the semiconductor layer and the semiconductor crystal lattice, wherein the semiconductor layer crystalizes by solid phase epitaxy to extend the semiconductor crystal lattice.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure will be understood from the following Detailed Description taken in connection with the appended claims and with reference to the attached drawing Figures in which:

FIGS. 1A-1K depict cross-sectional views of a semiconductor device at various progressive stages that may be fabricated as an example implementation of the present disclosure;

FIGS. 2A-2G depict cross-sectional views of a semiconductor device at various stages of fabrication according to some examples of the present disclosure;

FIGS. 3A-3C are flowcharts of IC fabrication methods according to some examples of the present disclosure; and

FIGS. 4A and 4B depict line scan profiles of oxygen through an amorphous silicon layer and a crystalline silicon layer before and after silicon ion implant, respectively, according to some examples of the present disclosure

### DETAILED DESCRIPTION

Examples of the disclosure are described with reference to the attached Figures in which like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of semiconductor devices including crystalline silicon layers formed from amorphous materials overlying substrates with composite surfaces are set forth below.

Epitaxy (prefix epi-means “on top of” and taxis means “ordered”) refers to a type of crystal growth or material deposition in which new crystalline layers are formed with one or more well-defined orientations with respect to an underlying substrate that may serve as a crystalline seed layer. The deposited crystalline film is called an epitaxial film or epitaxial layer. The relative orientation(s) of the epitaxial layer with respect to the seed layer may be defined in terms of the orientation of the crystal lattice of each material. For most epitaxial growths, the new layer is usually crystalline, with each crystallographic domain of an overlayer having a well-defined orientation relative to the substrate crystal lattice structure. In general, single domain epitaxy, which is the growth of an overlayer crystal with one well-defined orientation with respect to the substrate crystal, is more desirable.

One of the main commercial applications of single crystal layers is in the semiconductor industry, where the layers are formed on a substrate having a specific crystalline orientation defined by its Miller index. Several techniques are available for the fabrication of epitaxial layers comprising a variety of semiconductor materials, e.g., including but not limited to metalorganic vapor-phase epitaxy (MOVPE), liquid phase epitaxy (LPE), vapor phase epitaxy (VPE), solid phase epitaxy (SPE), molecular beam epitaxy (MBE), chemical beam epitaxy (CBE) and atomic layer epitaxy (ALE), etc. Depending in implementation, epitaxial processes may involve a variety of complex interactions of different materials, often extant in multiple phases, e.g., gas, liquid, and/or solid phases, that may take place in a specialized chamber for growing or forming epitaxial layers over the substrate. In some examples, an epitaxial process may generally include the following steps and/or phenomena: transport of reactants to the substrate in a reaction chamber, diffusion of reactants to substrate surface, adsorption of reactants on substrate, surface processes such as reaction and adlayer incorporation, desorption of products and/or byproducts, transfer of products/byproducts to main transport medium (e.g., gas), and exhausting/removal of gases and other byproducts away from the reaction chamber.

Solid phase epitaxy (SPE) occurs in a suitable thermal environment when an amorphous layer in contact with a single crystal template crystallizes epitaxially in the solid state by the rearrangement of atoms at the interface between the ordered and disordered phases. The ordered array of atoms on the crystalline side of the interface serves as a template for the layer-by-layer addition of atoms from the disordered amorphous material to the ordered crystalline solid. The amorphous-to-crystal (a/c) transformation occurs in the solid phase and may be induced by heating, e.g., by laser, or by ion or electron bombardment.

In an example SPE process, when an amorphous silicon film, e.g., a noncrystalline silicon film or partially amorphous film (generally referred to as “a-Si”) is deposited on a crystalline silicon (c-Si) substrate, native oxide (e.g., silicon dioxide (SiO₂)) is often formed at the interface between the deposited a-Si film and the underlying c-Si substrate. The presence of an amorphous native oxide film generally prevents the c-Si substrate from serving as a crystal lattice template for converting the a-Si film into a c-Si layer. Having a c-Si substrate layer with a composite surface that comprises different materials and/or compositions may also obstruct the conversion of deposited a-Si material into a c-Si layer because there may be native oxide formed between the a-Si material and any underlying c-Si material that is in direct contact with the a-Si material. Such a situation may be particularly disadvantageous where vertical integration of devices is desired because it hinders the formation of a top c-Si layer with suitable electrical characteristics used for fabricating upper level of devices over a lower level c-Si layer used for fabricating lower level devices.

Baseline techniques for removing native oxide include high temperature bake or argon sputtering that are applied before depositing a-Si material. Whereas such techniques may remove the native oxide material from a silicon substrate, they require specialized tooling, which can increase manufacturing cost. Further, sputtering techniques such as argon sputtering may not be desirable for use in vertical device integration flows because of the risk of potential damage to lower level devices.

Examples of the present disclosure recognize the foregoing challenges and shortcomings and provide a technical solution for fabricating semiconductor devices including c-Si layers based on SPE. In some arrangements, an implant technique, e.g., based on group IV implant species such as Sit, Si, Get, Ger, or a combination thereof, is implemented after depositing a-Si material over a c-Si substrate layer in order to fragment any native oxide formed between the a-Si material and the c-Si substrate layer. The fragmentation of the native oxide allows direct access or contact between the a-Si material and the underlying crystalline lattice structure, which serves as a template for reordering silicon in the a-Si material. Accordingly, the a-Si material may be converted to a suitable c-Si layer operable as an upper layer having desirable electrical properties for 3D device integration in some examples. Because no additional tooling or equipment is required for effectuating group IV implant processes according to the examples, no significant impact on manufacturing costs is expected. Whereas the examples herein may provide various structures, materials and processes that may engender these and other beneficial effects in a variety of device fabrication scenarios, no particular result is a requirement unless explicitly recited in a particular claim.

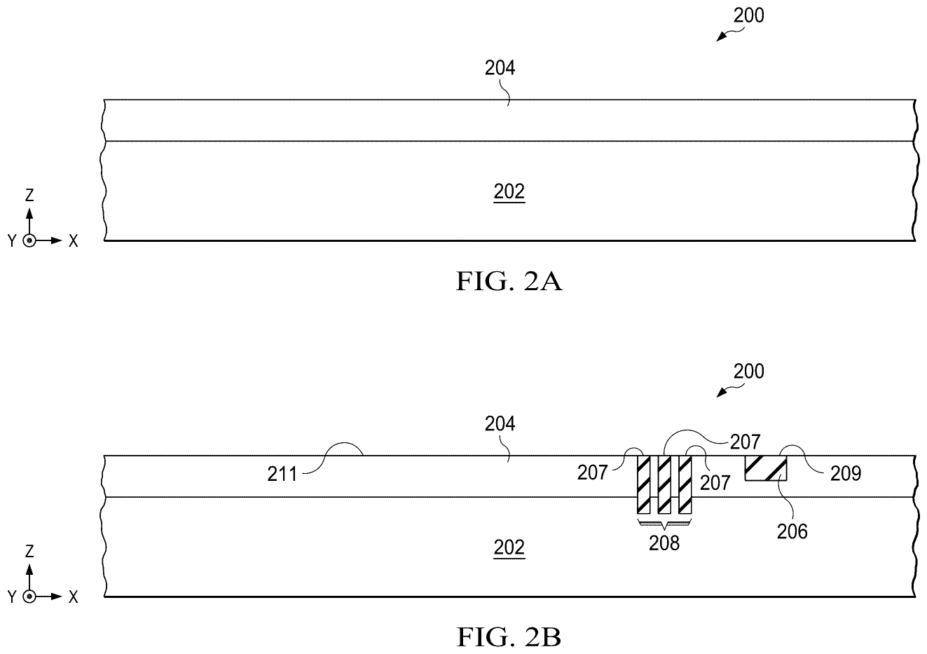

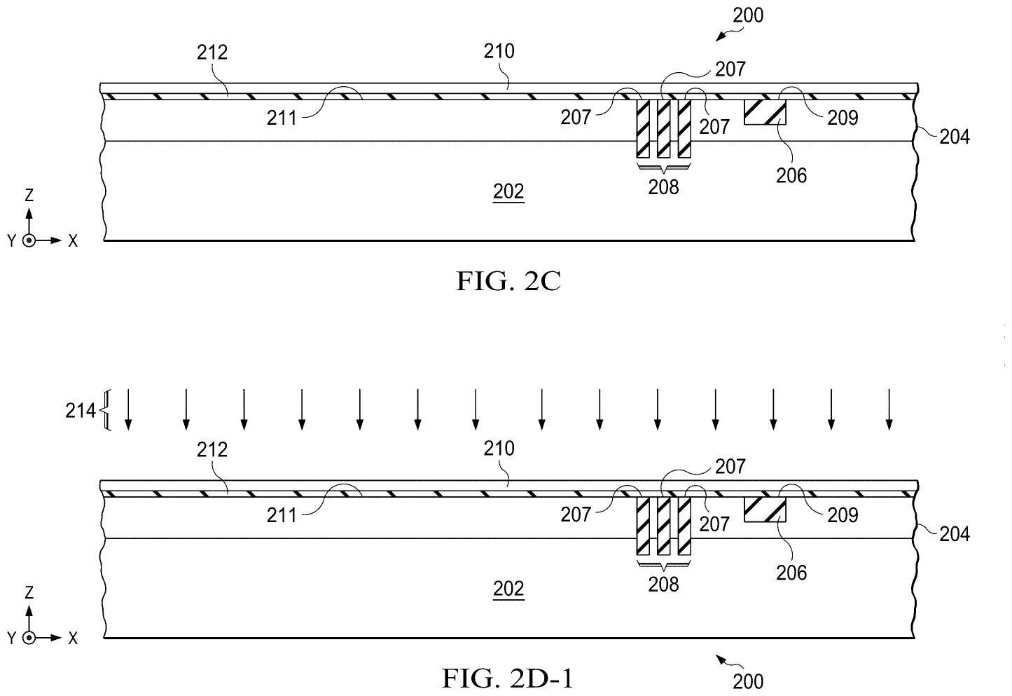

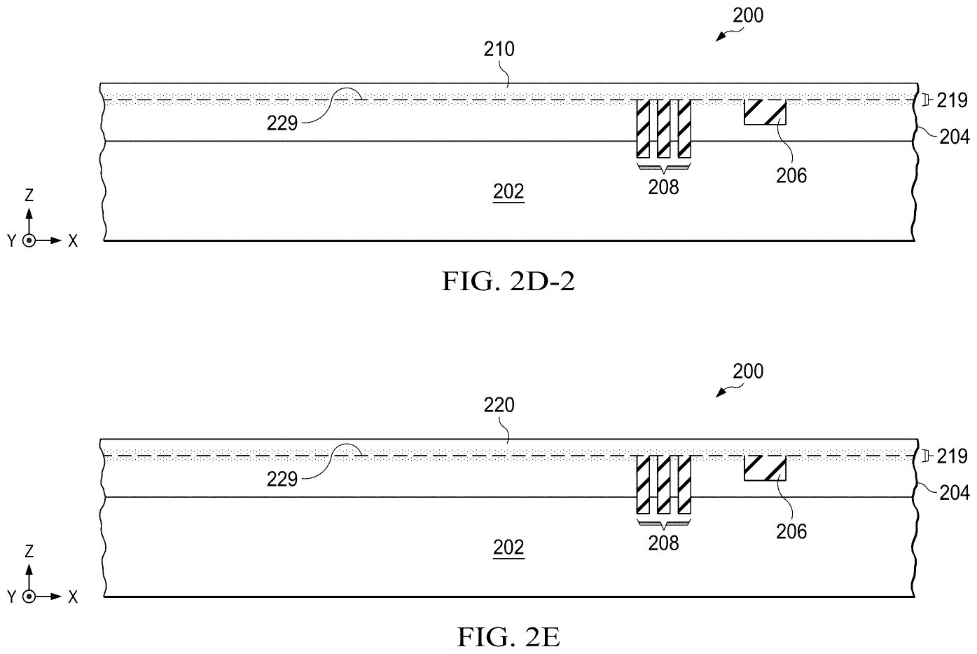

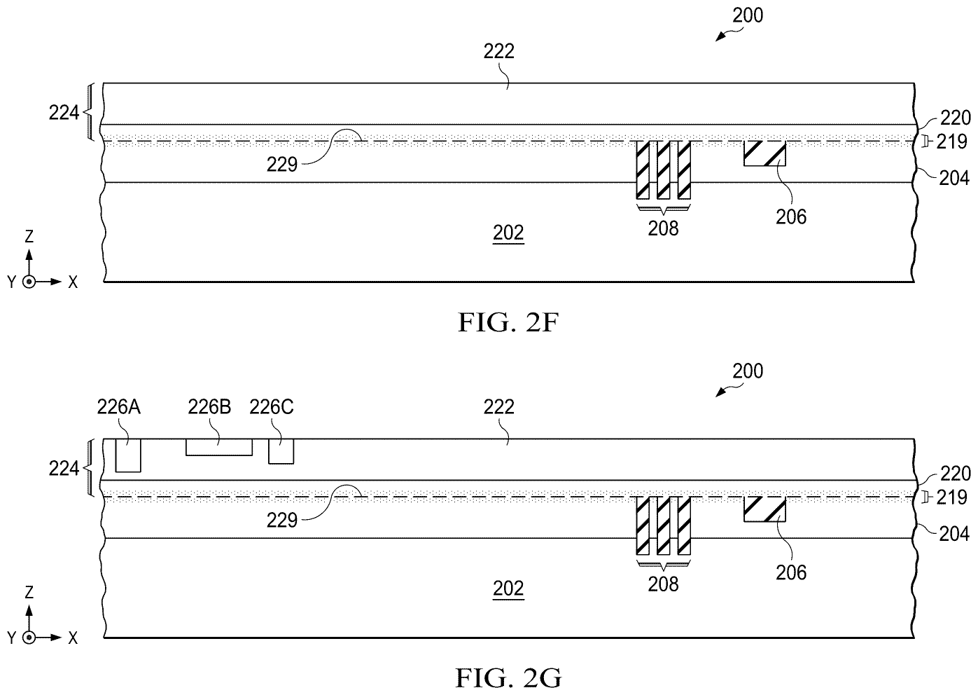

Referring to the drawings, FIGS. 2A-2G depict cross-sectional views of a semiconductor device 200 at various stages of fabrication that may include the formation of one or more crystalline silicon layers over composite surfaces according to some examples of the present disclosure. By way of illustration, the semiconductor device 200 is representative of a generalized integrated circuit (IC) device where multiple circuit components, also referred to as electronic components or devices, may be fabricated in a 3D device integration flow that allows the formation of various circuit components at different levels in or over a suitable semiconductor substrate, e.g., semiconductor substrate 202. In some versions of this example, the semiconductor substrate 202 may comprise doped silicon material (e.g., p-type) having a suitable crystallographic orientation such as {100}, {110}, {111}, etc., without limitation. In additional and/or alternative examples, other semiconductor materials such as Ge, SiGe, GaAs, SiC, GaN, other Group III-V materials, etc., may be used as a substrate in some implementations, where one or more doped epitaxial layers or single-crystal layers may be formed or provided in some arrangements. In further variations, the semiconductor substrate 202 may comprise a polycrystalline substrate, an amorphous substrate, a partial silicon-on-insulator (SOI) substrate, etc.

Depending on application, an example fabrication flow may be implemented using a variety of semiconductor technologies such as bipolar junction transistor (BJT) technologies, heterojunction bipolar transistor (HBT) technologies, metal oxide semiconductor (MOS) technologies, complementary metal oxide semiconductor (CMOS) technologies, double-diffused metal oxide semiconductor (DMOS) technologies, etc., including analog, digital and/or mixed signal device designs. In some examples, a combination of semiconductor technologies may be implemented, where different technologies suitable for respective types of product design may be integrated within the same chip or IC device, e.g., linear BiCMOS or LBC (a bipolar-CMOS combination technology where bipolar technology may be used for analog functions and CMOS may be used for digital logic design), BCD (a bipolar-CMOS-DMOS combination technology where DMOS may be integrated within the IC device for power and high-voltage portions that also has analog and digital portions), and the like. Accordingly, without being limited to a particular implementation, the semiconductor substrate 202 may comprise a portion of a semiconductor process wafer, e.g., an IC die, where the semiconductor device 200 may have been processed to include to one or more crystalline silicon (c-Si) layers, collectively shown as reference number 204.

In some arrangements, the c-Si layer(s) 204 overlying the semiconductor substrate 202 may have a thickness (e.g., 1 μm to 15 μm or more) suitable to accommodate various circuit components that may be fabricated therein according to the desired scheme of 3D device integration. In some arrangements, the c-Si layer(s) 204 may be doped, e.g., with boron, to have a first type conductivity (e.g., p-type). For purposes of some examples, the c-Si layer(s) 204 may be provided as a lower level layer, which may be referred to as a first c-Si layer, in a vertical stack of crystalline layers, and may comprise single-crystal layer(s) or epitaxial layer(s) formed using known or heretofore unknown techniques.

FIG. 2B depicts a stage of the semiconductor device 200 where one or more circuit components 206, 208 are formed in and/or extending through the first c-Si layer 204. For purposes of some examples, circuit components 206, 208 may be referred to as “buried devices”, “trench devices”, “lower level devices”, or the like, and may include trench capacitors in some implementations as will be set forth in detail further below. Some circuit components, e.g., circuit components 208, may extend into the semiconductor substrate 202, although it is not a requirement. Depending on the fabrication flow of the circuit components 206, 208, top surfaces 207, 209 of the circuit components 206, 208, respectively, may comprise materials (e.g., oxide, oxide-nitride-oxide (ONO), oxynitride, etc.) having a composition different from the composition of a top surface 211 of the first c-Si layer 204, which is generally a crystalline monolayer of the first c-Si layer 204 that is exposed after a suitable surface clean process subsequent to the formation of the circuit components 206, 208.

FIG. 2C depicts a stage where an a-Si layer 210 is formed over the first c-Si layer 204, including the circuit components 206, 208. In some arrangements, a polysilicon deposition process using e.g., chemical vapor deposition (CVD), physical vapor deposition (PVD), etc., may be implemented for forming a layer of suitable thickness depending on application. In some arrangements, thermal decomposition of silane (SiH₄) at around 500° C. to 600° C. may be implemented. In some arrangements, the a-Si layer 210 may be doped with appropriate dopants. Where the a-Si layer 210 is to be transformed into a crystalline seed layer for facilitating a subsequent epitaxy process, the thickness of the a-Si layer 210 may be accordingly selected or adjusted. In some arrangements, the a-Si layer 210 may have a thickness of around 35 nm to 55 nm, although other thicknesses may be provided in additional and/or alternative examples depending on implementation. Because of the interactions with ambient conditions, such as exposure to fabrication facility (“fab”) atmosphere, an oxide layer 212 of about 1 nm to 2 nm thick (referred to herein as a native oxide layer, generally comprising SiO₂) is formed at the interface between the a-Si layer 210 and the underlying c-Si layer 204, which generally hinders the transformation of a-Si material into a crystalline structure in SPE as noted previously.

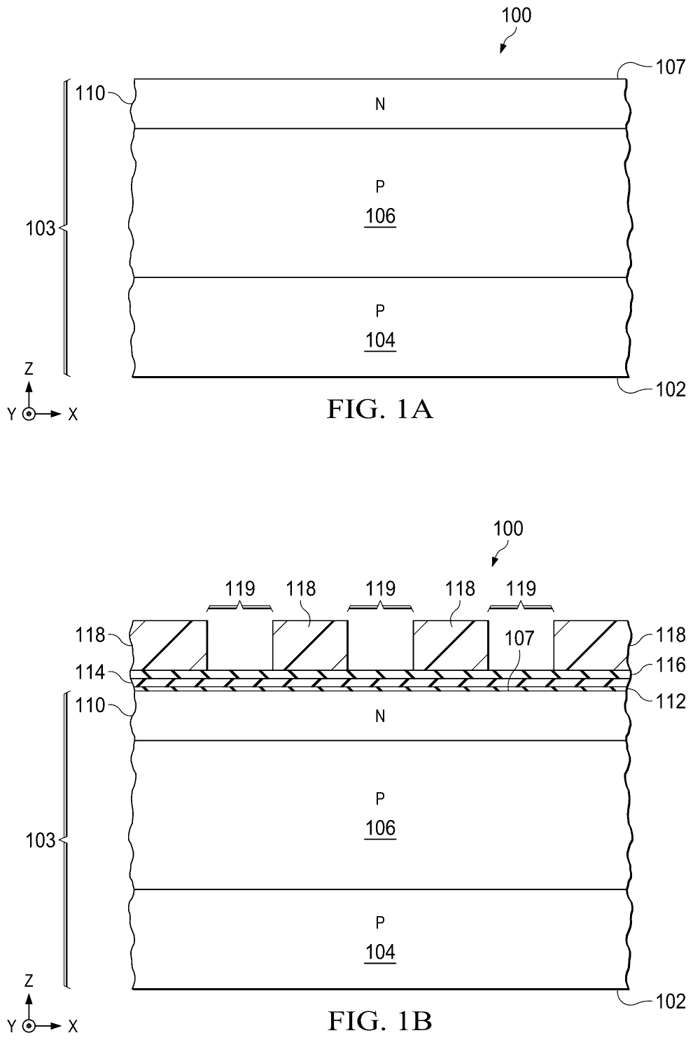

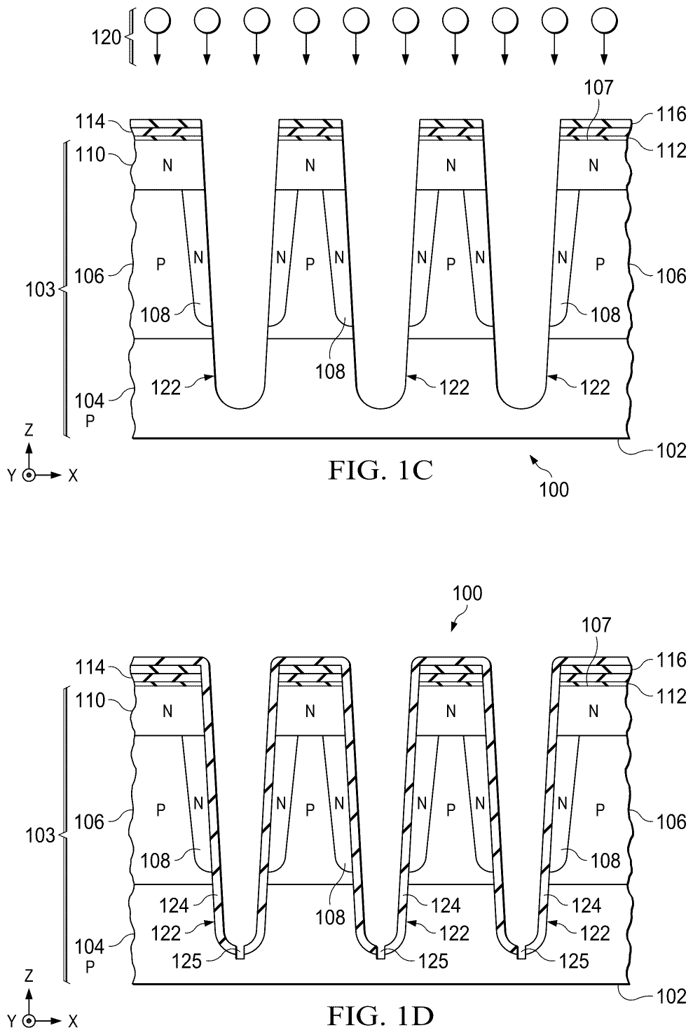

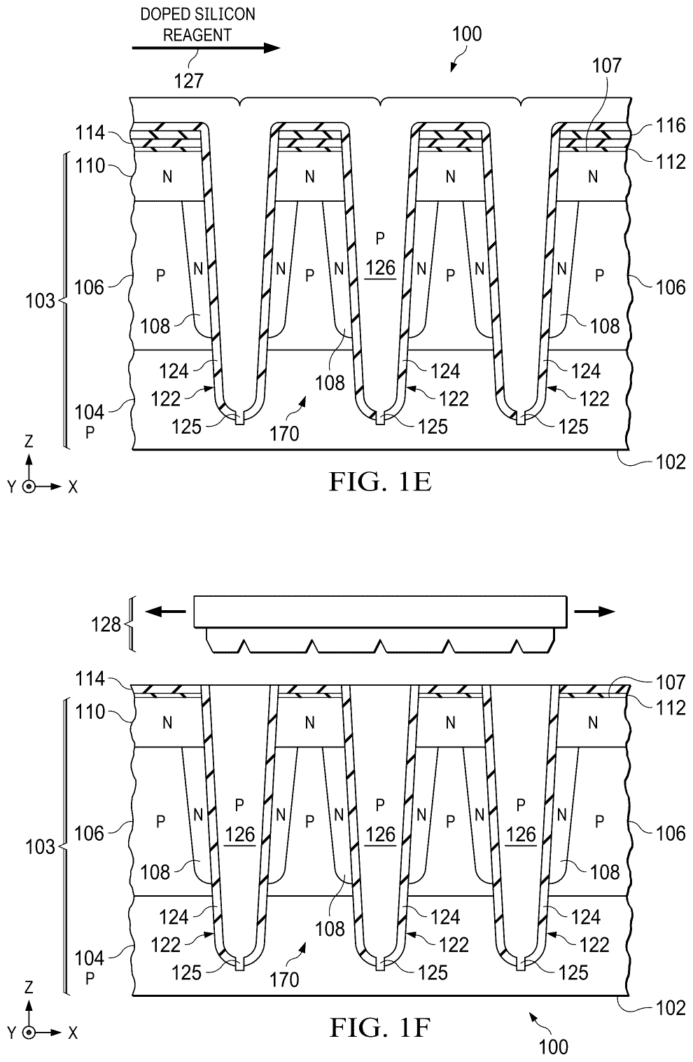

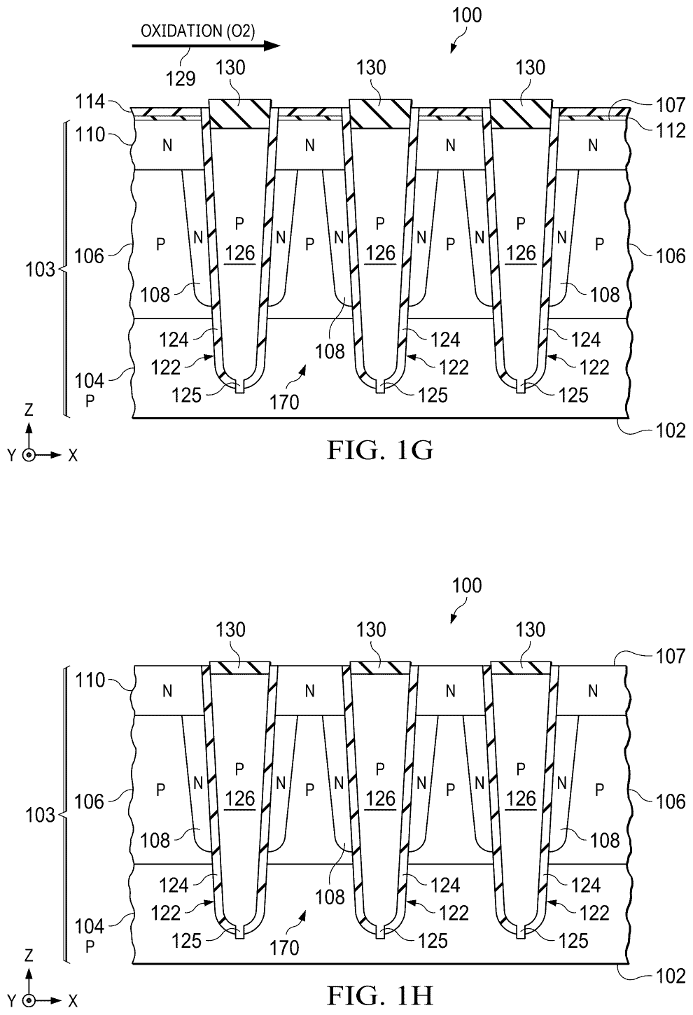

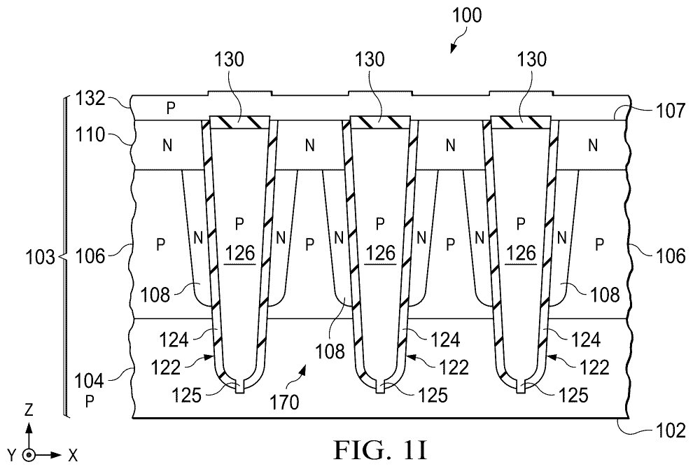

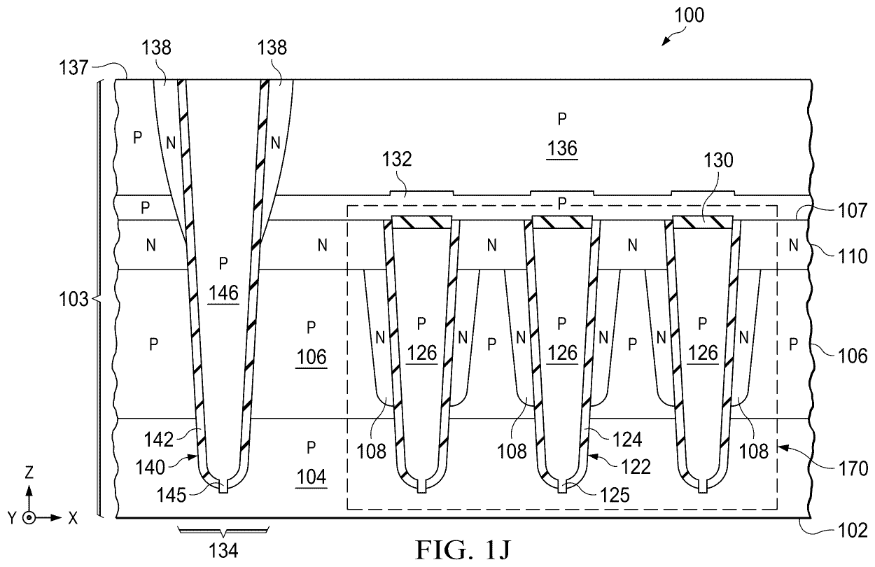

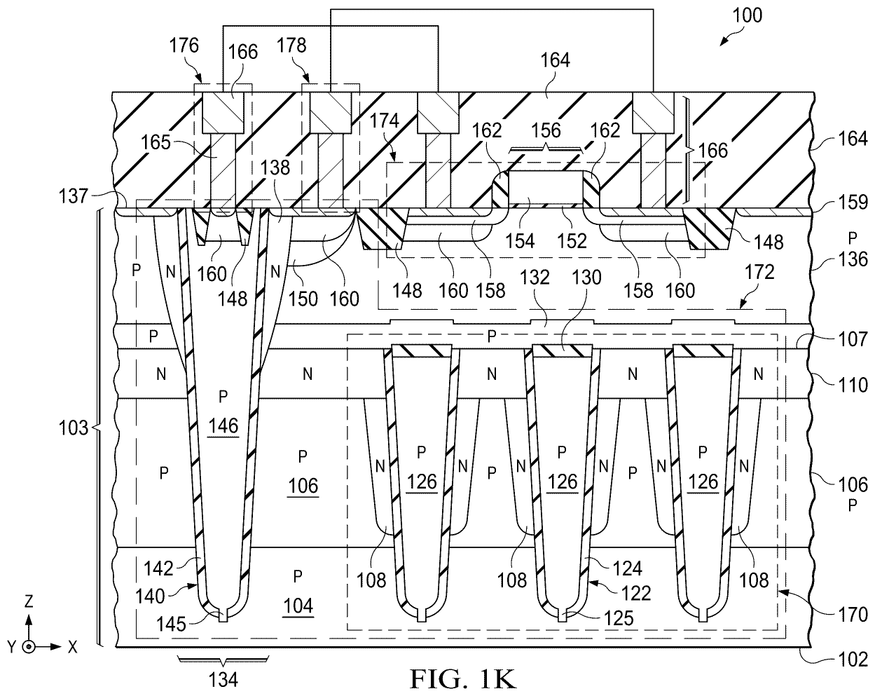

FIG. 2D-1 depicts an implant stage where group IV ions e.g., silicon ions (Si⁺ or Si⁻), germanium ions (Ge⁺ or Ge⁻) ions, or a combination thereof, having a suitable dose (e.g., about 4×10¹⁵ cm⁻²) and energy (e.g., about 50 keV) are implanted into the semiconductor device 200. As will be seen further below, additional and/or alternative variations as to the dosages and/or energies may be provided in some arrangements. In some versions, the dosage and/or energy of implant species 214 may be modulated based on the thickness of the a-Si layer 210 that needs to be penetrated so that the implant ions can reach the native oxide layer 212 and beneficially interact with the oxide material. For example, where Si⁺ implant is implemented, the silicon ions may break the S—O covalent bonds in the oxide material and replace the oxygen atoms with silicon, resulting in “siliconization” of the amorphous oxide material. Further, the silicon ions may disrupt or fissurize the oxide layer 212, thus creating areas between the a-Si layer 210 and the c-Si layer 204 that are devoid of an oxide barrier. Such areas facilitate direct contact or interface between the disordered phase silicon atoms of the a-Si layer 210 and the ordered phase monolayer of the top surface 211 of the c-Si layer 204, where a transformative ordering of the a-Si material may be effectuated in a subsequent SPE process using the crystalline template provided by the top surface 211.

FIG. 2D-2 depicts a cross-sectional view of the semiconductor device 200 after completing the group IV ion implant process set forth above. Because of the ionic disruption of the native oxide material, oxygen proximate to an interface 229, which may be represented by a peak of an oxide continuum between the c-Si layer 204 and the a-Si layer 210, may be redistributed, resulting in remnants of oxide material that may form a layer 219 of distributed silicon oxide inclusions at or near the interface 229.

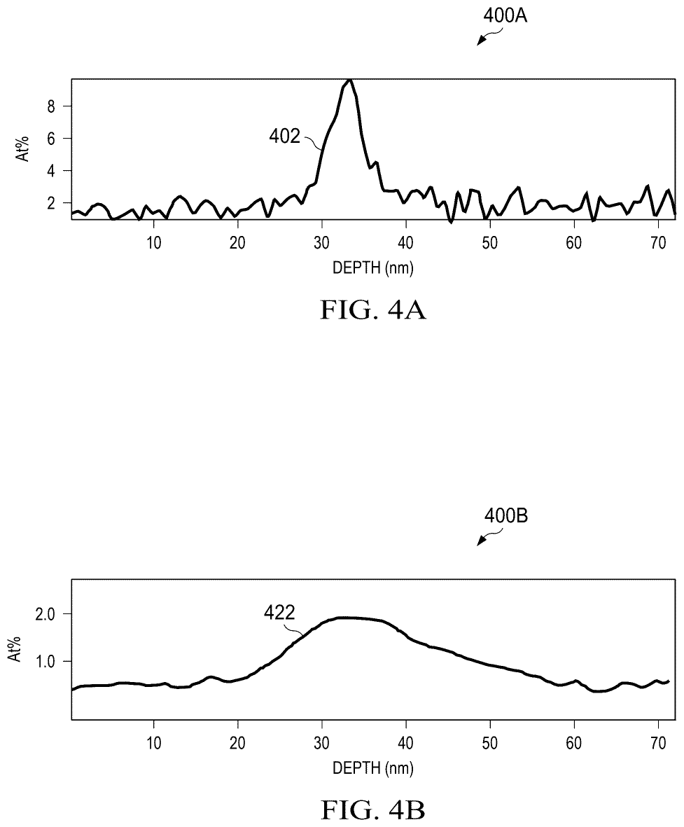

Turning to FIGS. 4A and 4B, depicted therein are line scan profiles of oxygen distributions proximate to the interface 229 between the a-Si layer 210 and the c-Si layer 204 before and after the silicon ion implant, respectively, according to some examples of the present disclosure. In FIG. 4A, a line scan profile 400A illustrates a trace 402 of oxygen in relative or normalized atomic percentage (%) plotted against a depth (e.g., along a surface normal of the semiconductor device 200) from a reference point above the interface 229. As illustrated, prior to silicon ion implant, the trace 402 shows a peak oxygen percentage at a depth of around 35 nm. In FIG. 4B, a line scan profile 400B illustrates a trace 422 of oxygen in relative or normalized atomic percentage (%) after the implant, where a concentration peak occurring at around a depth of 35 nm is reduced to about 25% of the initial oxygen concentration before the implant. Further, the oxygen content may be less tightly distributed after the implant than before the implant according to some examples herein.

FIG. 2E depicts an SPE stage of the semiconductor device 200 after forming the layer 219 of distributed silicon oxide inclusions, resulting in the conversion of the a-Si layer 210 into a crystalline form, e.g., a c-Si layer 220, over the first c-Si layer 204. In some examples, the SPE process may be implemented using a furnace anneal process, where the c-Si layer 220 may be formed as a second c-Si layer over the first c-Si layer 204. Depending on implementation, SPE may be performed at suitable temperature ranges, which may be followed by an anneal step as will be set forth in detail further below. Additionally, and optionally, the resulting c-Si layer 220 may be doped with suitable dopants depending on application, although this is not a requirement. Regardless of whether the a-Si layer 210 is initially doped or not (e.g., in the stage shown in FIG. 2C), the c-Si layer 220 may receive dopants from adjacent structures, e.g., the c-Si layer 204, by diffusion in subsequent processing.

FIG. 2F depicts a stage of the semiconductor device 200 with additional c-Si layers 222 formed or grown over the c-Si layer 220 using known or heretofore unknown processes, where the c-Si layer 220 which may be used as a seed layer in some arrangements as set forth previously. Depending on implementation, the c-Si layer 220 formed by SPE and the subsequent c-Si layer(s) 222 may be configured as an upper level layer 224 for fabricating various circuit components therein according to a desired 3D device integration scheme.

FIG. 2G depicts a stage of the semiconductor device 200 including a plurality of circuit components 226A-C, which may be formed in the upper level c-Si layer 224 formed according to the examples herein. In some arrangements, the circuit components 226A-C may comprise transistors, etc., which may be integrated with one or more lower level devices or circuit components 206, 208.

Turning to FIGS. 1A-1K, cross-sectional views of an example semiconductor device 100 are depicted in successive stages of a 3D device integration process flow where one or more c-Si layers may be formed according to examples herein. In an example implementation, one or more circuit components such as buried trench capacitors may be fabricated as part of the semiconductor device 100 in a lower c-Si layer whereas additional circuit components such as transistors, etc. may be formed in an upper c-Si layer formed on top of the lower c-Si layer, roughly analogous to the arrangement shown in FIG. 2G. Although a semiconductor device including an integrated buried trench capacitor component is illustrated herein, the examples of the present disclosure are not limited thereto, implied or otherwise.

Referring to FIG. 1A in particular, the semiconductor device 100 includes a semiconductor substrate 102 that may comprise multi-layered semiconductor material 103, where the layers may comprise layers of doped silicon. In additional and/or alternative examples, the substrate 102 may include a dielectric material, such as silicon dioxide or sapphire, to provide at least a partial SOI substrate. In this example, the substrate 102 may include a base or bulk layer 104, which may be part of a silicon wafer, not specifically shown in this Figure. The base layer 104 may have a first conductivity type, which is shown as p-type in this example. A first epitaxial layer 106 is formed on the base layer 104. The first epitaxial layer 106 includes primarily silicon, and may consist essentially of silicon and dopants, such as boron. The first epitaxial layer 106 has a first epitaxial top surface 107. In this example, the first epitaxial layer 106 may have the first conductivity type, i.e., p-type. The first epitaxial layer 106 may have a thickness of about 5 μm to 15 μm, by way of example. In some representative versions, the epitaxial layer 106 is roughly analogous to the first c-Si layer 204 described above, and may be formed or grown using a variety of technologies as previously set forth.

A buried layer 110 may be formed in the first epitaxial layer 106. The buried layer 110 has a second conductivity type, opposite to the first conductivity type. In this example, the second conductivity type is n-type. The buried layer 110 may be formed by implanting dopants of the second conductivity type, such as phosphorus, arsenic, or antimony, into the first epitaxial layer 106. The buried layer 110 may have an average dopant density greater than twice an average dopant density of the first epitaxial layer 106. An annealing step may follow after the buried layer implant.

In FIG. 1B, a pad oxide layer 112 may be formed on the first epitaxial top surface 107 of the first epitaxial layer 106. The pad oxide layer 112 may include primarily silicon dioxide, may be formed by a thermal oxidation process or a thermal CVD process, and may have a thickness of 50 nm to 200 nm, by way of example. A nitride cap layer 114 may be formed on the pad oxide layer 112. The nitride cap layer 114 may include primarily silicon nitride, may be formed by a low-pressure CVD (LPCVD) furnace process, and may have a thickness of 100 nm to 500 nm, for example. A hard mask layer 116 may be formed on the nitride cap layer 114. The hard mask layer 116 may include primarily silicon dioxide, may be formed by a plasma enhanced CVD (PECVD) process, and may have a thickness of 1 μm to 3 μm, depending on a depth of subsequently-formed buried capacitor trench 122, shown in FIG. 1C. The pad oxide layer 112 may provide stress relief between the first epitaxial layer 106 and a combination of the nitride cap layer 114 and the hard mask layer 116. The nitride cap layer 114 may provide a stop layer for subsequent etch and planarization processes. The hard mask layer 116 may provide a hard mask during a subsequent buried capacitor etch process 120 illustrated in FIG. 1C to form the buried capacitor trench 122. Subsequently, a buried capacitor trench mask 118 may be formed on the hard mask layer 116 with buried capacitor trench mask openings or apertures 119, which expose the hard mask layer 116 in an area for the buried capacitor trench 122. The buried capacitor trench mask 118 may include photoresist, and may optionally include anti-reflection material such as a bottom anti-reflection coat (BARC). The buried capacitor trench mask 118 may be formed by a photolithographic process.

In FIG. 1C, a buried capacitor etch process 120 is performed to form the buried capacitor trench 122 in the first epitaxial layer 106. A buried capacitor trench 122 is formed for each desired capacitor cell, the capacitor cells forming an array of capacitor cells. The buried capacitor etch process 120 may include multiple steps. In one implementation, a hard mask etch may be first performed to remove the hard mask layer 116 where exposed by the buried capacitor trench mask 118 of FIG. 1B. A silicon etch may then be performed to remove the nitride cap layer 114, the pad oxide layer 112, and the first epitaxial layer 106 in regions that are exposed by the hard mask layer 116 to form the buried capacitor trench 122. The buried capacitor trench 122 extends from the first epitaxial top surface 107 into the first epitaxial layer 106 and may extend into the base layer 104. During the silicon etch, the buried capacitor trench mask 118 may also be partially or completely removed, leaving the hard mask layer 116 to prevent the area outside of the buried capacitor trench 122 from being etched.

FIG. 1C depicts the buried capacitor etch process 120 at completion, where the buried capacitor trench mask 118 has been removed by subsequent buried capacitor trench etch clean-up process (not specifically shown). The organic polymers in the buried capacitor trench mask 118 may be removed using an oxygen plasma, followed by a series of wet etch processes, including an aqueous mixture of sulfuric acid and hydrogen peroxide, an aqueous mixture of ammonium hydroxide and hydrogen peroxide, and/or an aqueous mixture of hydrochloric acid and hydrogen peroxide, by way of example.

A buried capacitor deep well (DWELL) 108 may be formed in the first epitaxial layer 106, extending past the bottom edge of the buried layer 110 along edges of the buried capacitor trench 122, as shown in FIG. 1C. The buried capacitor DWELL 108 may be formed by implanting dopants of the second conductivity type, such as phosphorus, using an angled implant to implant the dopants along edges of the buried capacitor trench 122 beyond the buried layer 110 into the first epitaxial layer 106, followed by a thermal drive to diffuse and activate the implanted dopants. The buried capacitor DWELL 108 may have an average concentration of the dopants of the second conductivity type that is 2 to 10 times greater than an average concentration of dopants of the first conductivity type in the first epitaxial layer 106 outside of the buried capacitor DWELL 108.

In FIG. 1D, a buried capacitor trench liner dielectric layer 124, also referred to as a trench liner dielectric layer, is formed in the buried capacitor trench 122, contacting the first epitaxial layer 106 and the base layer 104 as well as the buried capacitor DWELL 108 and buried layer 110. The trench liner dielectric layer 124 may extend over the hard mask layer 116, the nitride cap layer 114, and the pad oxide layer 112. The trench liner dielectric layer 124 may include a single layer of a silicon-nitrogen compound or a silicon dioxide compound or may include multiple layers of silicon-nitrogen compounds, silicon dioxide compounds, or other dielectric materials. After the formation of the trench liner dielectric layer 124, a trench liner dielectric layer etch process (not specifically shown) is used to form a trench liner gap 125 through the bottom of trench liner dielectric layer 124 exposing the base layer 104.

In FIG. 1E, a trench-fill material 126 is formed in the buried capacitor trench 122 on the trench liner dielectric layer 124. The trench-fill material 126 is electrically conductive. The trench-fill material 126 includes primarily silicon, and may be implemented as polycrystalline silicon (i.e., polysilicon). Alternatively, the trench-fill material 126 may be implemented as amorphous silicon or semi-amorphous silicon. The trench-fill material 126 may have the first conductivity type, p-type in this example. The trench-fill material 126 may have an average concentration of dopants of 5×10¹⁸ cm⁻³ and 1×10²⁰ cm⁻³, operable to provide a low equivalent resistance for a buried trench capacitor array 170 comprising a plurality of capacitor cells formed in respective trenches 122. The trench-fill material 126 may be formed by thermal decomposition of a silicon-containing reagent gas that includes a doped polysilicon reagent 127. The trench-fill material 126 fills the buried capacitor trench 122 and may extend outside of the buried capacitor trench 122.

In FIG. 1F, the trench-fill material 126 and the trench liner dielectric layer 124 are removed from outside of the buried capacitor trench 122. The trench-fill material 126 and the trench liner dielectric layer 124 may be removed by a planarization process, such as a chemical mechanical polish (CMP) process 128, as indicated in FIG. 1F. Alternatively, the trench-fill material 126 and the trench liner dielectric layer 124 may be removed by an etch back process. The process of removing the trench-fill material 126 and the trench liner dielectric layer 124 outside of the buried capacitor trench 122 leaves the trench-fill material 126 on the trench liner dielectric layer 124 in the buried capacitor trench 122. The process of removing the trench-fill material 126 and the trench liner dielectric layer 124 may leave the nitride cap layer 114 and the pad oxide layer 112 remaining on the first epitaxial top surface 107 of the first epitaxial layer 106. The nitride cap layer 114 may provide a selective template layer for the subsequent polysilicon oxidation process 129 shown in FIG. 1G.

In FIG. 1G, a polysilicon oxidation process 129 is used to form a buried capacitor silicon dioxide cap 130 configured to provide a dielectric barrier over the trench-fill material 126 of the buried trench capacitor array 170. The polysilicon oxidation process 129 may use oxygen or oxygen and steam at high temperature to oxidize the trench-fill material 126 at the first epitaxial top surface 107 of the first epitaxial layer 106. The nitride cap layer 114 prevents oxidation in regions other than the trench fill material 126.

In FIG. 1H, the nitride cap layer 114 and the pad oxide layer 112 are removed. The nitride cap layer 114 may be removed by a wet etch process using an aqueous solution of phosphoric acid at 140° C. to 170° C. The pad oxide layer 112 may be removed by a wet etch process using an aqueous solution of buffered hydrofluoric acid. The pad oxide layer 112 removal process is optimized to remove the pad oxide layer 112, but not to remove excess buried capacitor silicon dioxide cap 130 to the point that it would affect the dielectric integrity of the buried capacitor silicon dioxide cap 130.

In FIG. 1I, an epitaxial silicon capping layer 132 is deposited over the buried capacitor silicon dioxide cap 130. The epitaxial silicon capping layer 132 has the first conductivity type, p-type in this example. The epitaxial silicon capping layer 132 may be up to 1 μm to 3 μm by way of example. The epitaxial silicon capping layer 132 may contain p-type dopants such as boron at a concentration of 1×10¹⁵ atoms/cm³ to 1×10¹⁶ atoms/cm³.

In some arrangements, SPE is used for forming the epitaxial silicon capping layer 132, e.g., by transforming a-Si material deposited over the epitaxial top surface 107 and the oxide caps 130 of the capacitor cells, which together provide a composite surface that may hinder the amorphous-to-crystalline conversion process as described previously. Accordingly, in examples herein, a group IV implant process as set forth above in reference to FIGS. 2A-2G may be implemented for forming a crystalline seed layer that may be used for extending the crystal lattice of the first epitaxial layer 106 into a c-Si layer operable as the epitaxial silicon capping layer 132.

In FIG. 1J, a top epitaxial silicon 136 layer with first conductivity type doping (e.g., p-type) and an integrated deep trench 134 are formed. In some arrangements, after the formation of the epitaxial silicon capping layer 132, the top epitaxial silicon 136 layer may be formed, e.g., deposited or grown, having a thickness of about 5 μm to 15 μm in some examples. The top epitaxial silicon layer 136 has a top epitaxial silicon top surface 137, and may contain p-type dopants such as boron at a concentration of 1×10¹⁵ atoms/cm³ to 1×10¹⁶ atoms/cm³, by way of example. After the formation of the top epitaxial silicon 136 layer, a pattern and implant step may be used to form a deep trench DWELL region 138, which may have the second conductivity type (e.g., n-type). Alternatively, the deep trench DWELL region 138 may be formed after the formation of the integrated deep trench 134.

The integrated deep trench 134 makes an electrical connection from the top epitaxial silicon top surface 137 of the semiconductor device 100 to the base layer 104. In general, the formation of the integrated deep trench 134 may include an integrated deep trench hard mask layer formation step, a photolithographic pattern step, a plasma etch step, and a clean-up step (none specifically shown).

After the formation of the deep trench 140, a deep trench liner 142 is deposited, which may comprise a dielectric layer having a thickness of about 5 nm to 30 nm in some examples. The deep trench liner 142 may be a single layer or multiple layers of dielectric materials such as silicon nitride, silicon oxynitride and silicon dioxide, etc. After the deposition of the deep trench liner 142, a deep trench liner etch process is used to create a deep trench liner gap 145 which provides an electrically conductive path between the subsequently deposited electrically conductive deep trench poly silicon fill 146 and the base layer 104 of the substrate 102. After the formation of the deep trench liner gap 145, a polysilicon deposition process is used to form the electrically conductive deep trench polysilicon fill 146 on the deep trench liner 142. In an example, the electrically conductive deep trench polysilicon fill 146 is p-type doped with a dopant such as boron. Any overburden comprising the electrically conductive deep trench polysilicon fill 146 and/or deep trench liner 142 outside of the deep trench 140 are subsequently removed by a CMP or etch back process (not specifically shown).

In FIG. 1K, the remaining process steps necessary to complete the formation of the integrated deep trench 134 and the formation of a circuit component 174 (a CMOS transistor in this example) are shown. The buried trench capacitor array 170 or a portion of the buried trench capacitor array 170 may be under the circuit component 174. A well 150 is implanted to provide electrical contact to the deep trench deep well region 138 of the integrated deep trench 134, the integrated buried capacitor 172 and the buried trench capacitor array 170. A field oxide 148 is formed in a series of steps including, e.g., a pattern step, an etch step, a field oxide fill step, and one or more CMP or etch back steps (none specifically shown). The field oxide 148 provides isolation for the circuit component 174 as well as the integrated deep trench 134.

The remaining components of the CMOS transistor of the example device shown in FIG. 1K comprise a gate oxide 152 on the top epitaxial silicon top surface 137 and gate electrode material 154 on the gate oxide 152, which forms the transistor gate electrode 156. The transistor includes a halo implant region 158 and a source/drain implant region 160. A sidewall 162 is formed on the lateral surfaces of the gate electrode 157. A metal silicide 159 may be formed on exposed silicon surfaces on the top epitaxial silicon top surface 137 of the silicon. A pre-metal dielectric (PMD) layer 164 is formed on or over the top epitaxial silicon top surface 137 of the semiconductor device 100. Contacts 165 and metallization 166 are formed to provide electrical contact between a first buried trench capacitor terminal 176 of the integrated buried capacitor 172, a second buried trench capacitor terminal 178 of the integrated buried capacitor 172 and the circuit component 174.

The first buried trench capacitor terminal 176 provides electrical connection through the integrated deep trench 134 and through the substrate 102 to the electrically conductive buried capacitor trench-fill material 126. The second buried trench capacitor terminal 178 provides electrical connection through the well 150 and the deep trench deep well region 138 to the buried trench capacitor DWELL 108. Additional details and variations relating to the foregoing buried trench capacitor arrangement may be found in U.S. Patent Application Publication No. 2024/0113102, which is incorporated by reference herein in its entirety for all purposes.

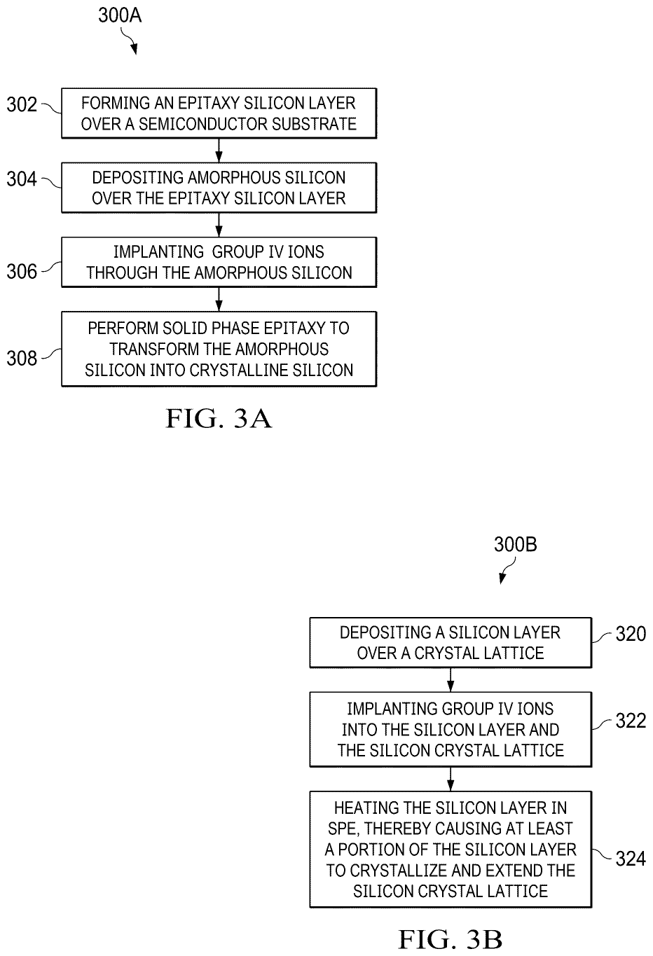

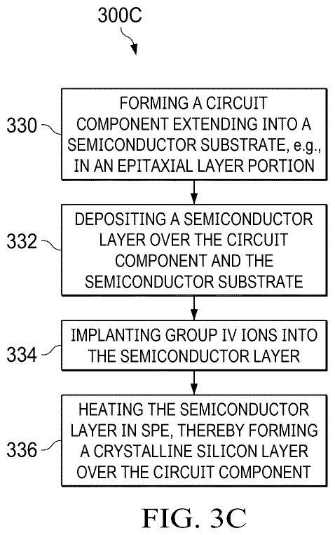

FIGS. 3A-3C are flowcharts of IC fabrication methods according to some examples of the present disclosure, where different steps, acts, functions and/or blocks may be combined or otherwise rearranged in multiple combinations. Method 300A shown in FIG. 3A may commence with forming an epitaxy silicon layer over a semiconductor substrate (block 302), which relates to some aspects of the processes described in respect of FIG. 2A. At block 304, amorphous silicon may be deposited over the epitaxy silicon layer, which relates to some aspects of the processes described in respect of FIG. 2C. At block 306, a group IV implant may be performed where the group IV ions having sufficient dosage and energy penetrate through the amorphous silicon and potentially some depth of the epitaxy silicon layer, which relates to some aspects of the processes described in respect of FIGS. 2D-1 and 2D-2. At block 308, an SPE process may be performed to transform, convert or otherwise render the amorphous silicon into crystalline silicon, which relates to some aspects of the processes described in respect of FIGS. 2D-1 and 2D-2 and FIG. 2E.

Additional variations, adaptations and/or modifications of the foregoing scheme are set forth below in reference to FIGS. 3B and 3C. Method 300B of FIG. 3B may commence with depositing a semiconductor layer, e.g., silicon layer, over a crystal lattice (block 320). As noted previously, a silicon dioxide layer may be present on or over the crystal lattice in some scenarios. At block 322, group IV ions may be implanted into the semiconductor layer and the silicon crystal lattice. At block 324, the semiconductor layer is heated in a suitable SPE chamber, which causes at least a portion of the silicon layer to crystallize and extend or otherwise grow the silicon crystal lattice. Method 300C of FIG. 3 may commence with forming a circuit component extending into a semiconductor substrate, e.g., in an epitaxial layer portion, as set forth at block 330. As described previously, an example circuit component may comprise one or more buried trench capacitor cells, without limitation. At block 332, a semiconductor layer, e.g. a silicon layer, may be deposited over the circuit component and the semiconductor substrate, where the semiconductor layer may be in contact with the semiconductor substrate. At block 334, group IV ions may be implanted into and/or through the semiconductor layer. At block 336, the semiconductor layer may be heated in an SPE chamber as set forth above, resulting in the formation of a crystalline semiconductor layer over the circuit component. In some variations involving 3D device integration, one or more additional circuit components may be formed in the crystalline semiconductor layer (e.g., a c-Si layer). Depending on implementation, an additional circuit component may comprise a transistor such as a laterally diffused MOS transistor (LDMOS) transistor, a drain extended metal oxide semiconductor (DEMOS) transistor, a bipolar junction transistor, a junction field effect transistor, a gated bipolar semiconductor device, a gated unipolar semiconductor device, or an insulated gate bipolar transistor (IGBT), etc. In other arrangements, the electronic component is a silicon-controlled rectifier (SCR), a metal oxide semiconductor (MOS)-triggered SCR, a MOS-controlled thyristor, a gated diode, an amplifier, or a Schottky diode, etc., by way of example.

Additional and/or alternative variations with respect to some of the foregoing example IC fabrication methods are set forth below in further detail.

In some arrangements, a semiconductor wafer having a composite surface, such as described previously, may undergo a hydrogen fluoride (HF) clean to remove silicon oxide on the surface. After the clean, the surface of the semiconductor wafer may be rinsed with deionized (DI) water and vapor dried. Subsequently, the semiconductor wafer may be exposed to a purge environment, e.g., N₂ purge, to minimize silicon oxide growth due to reaction with any ambient O₂.

A deposition step may follow thereafter, where an a-Si layer may be deposited over the surface of the semiconductor wafer, where the thickness of the layer may be around 20 nm to 80 nm. The deposition may be carried out in an LPCVD furnace. In some arrangements, the deposition may be performed at temperature ranges from around 500° C. to around 550° C. or lower in order to prevent microcrystalline Si from growing in amorphous silicon, which could negatively affect the quality of epitaxial silicon formation through SPE.

A group IV ion implant step may follow thereafter, where species such as Si⁺, Ge⁺ or any combination of Si⁺ and Get may be implanted into the semiconductor wafer to break through the native SiO₂ layer between the amorphous silicon and the epitaxial silicon and to completely amorphize the amorphous silicon layer, as well as to increase the stress in the amorphous silicon where Ge⁺ is implanted. The implant energy may be selected depending on the thickness of the amorphous silicon, typically with an implant energy ranging from around 20 keV to around 80 keV, and at a total dose of around 8×10¹⁵/cm² or higher.

In some optional implementations, dopants such as phosphorus (P), arsenic (As), or boron (B) may be implanted to dope the amorphous silicon, where implant energies suitable for the implanted species to reach the bottom of the a-Si layer, with doses of around 5×10¹⁵/cm² or higher, may be used.

An SPE anneal process may follow, which may be performed in a furnace at temperatures ranging from around 550° C. to around 700° C. for around 3 to 6 hours. A rapid thermal anneal (RTA) may then be performed to eliminate or reduce the end of range (EOR) defects that might have been created due to Sit, Get or a combination implant. In some examples, RTA may be performed at temperatures ranging from around 1000° C. to around 1150° C. for 10 seconds to 120 seconds with a temperature ramp up and ramp down rate of at least 20° C. per second, without limitation.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. In addition, terms such as “over”, “under”, “below”, etc. relative to the spatial orientation of two components does not necessarily mean that one component is immediately or directly over or above the other component, or that one component is immediately or directly under or below the other component. Further, the features and/or components of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A method of forming an integrated circuit (IC), comprising:
forming a circuit component extending into a semiconductor substrate;
depositing a silicon layer over the circuit component and the semiconductor substrate;
implanting group IV implant species into the silicon layer; and
heating the silicon layer, thereby forming a crystalline silicon layer over the circuit component.

2. The method of claim 1, wherein the circuit component is a capacitor.

3. The method of claim 1, wherein the crystalline silicon layer is a seed layer, and further comprising forming an epitaxial silicon layer on the seed layer.

4. The method of claim 3, further comprising forming a transistor extending into the epitaxial silicon layer.

5. The method of claim 1, wherein the silicon layer is amorphous before the implanting.

6. The method of claim 1, wherein the silicon layer has a thickness in a range from about 20 nm to about 80 nm before the implanting.

7. The method of claim 1, wherein the implanting includes implanting ions with an energy ranging from about 20 keV to about 80 keV and a dose of about 8×10¹⁵ cm⁻².

8. The method of claim 1, wherein the crystalline silicon layer extends over and touches a silicon oxide layer.

9. The method of claim 1, wherein the implanting at least partially breaks up an oxide layer between the silicon layer and the semiconductor substrate.

10. The method of claim 1, wherein the crystalline silicon layer is a first crystalline silicon layer and the semiconductor substrate includes a second crystalline silicon layer through which the circuit component extends.

11. The method of claim 1, wherein the group IV implant species comprises Si ions, Ge ions and/or a combination of both.

12. The method of claim 1, further comprising a rapid thermal anneal (RTA) step after heating the silicon layer, the RTA step performed at temperatures ranging from around 1000° C. to around 1150° C. for about 10 seconds to 120 second, including a temperature ramp-up and ramp-down rate of at least 20° C. per second.

13. A method, comprising:
depositing a silicon layer over a silicon crystal lattice; and
implanting silicon ions into the silicon layer and the silicon crystal lattice, wherein the silicon layer crystalizes by solid phase epitaxy to extend the silicon crystal lattice.

14. The method of claim 13, wherein the silicon layer is amorphous before the implanting and has a thickness of about 20 nm to 80 nm.

15. The method of claim 13, wherein the implanting includes implanting the silicon ions at a dosage and having an energy level that results in disrupting a silicon oxide layer between the silicon layer and the silicon crystal lattice.

16. The method of claim 15, wherein the silicon ions fissurize the silicon oxide layer, thereby resulting in contact between the silicon crystal lattice and the silicon layer.

17. The method of claim 13, further comprising forming, prior to depositing the silicon layer, a buried trench capacitor extending into the silicon crystal lattice.

18. The method of claim 13, further comprising:
forming, after crystallizing at least a portion of the silicon layer as a seed layer, an epitaxial silicon layer over the seed layer; and
forming a transistor extending into the epitaxial silicon layer.

19. A semiconductor device, comprising:
a semiconductor substrate;
a first crystalline silicon layer over the semiconductor substrate;
an electronic component extending into the first crystalline silicon layer;
a second crystalline silicon layer over the electronic component and the first crystalline silicon layer; and
a layer of distributed silicon oxide inclusions between the first crystalline silicon layer and the second crystalline silicon layer.

20. The semiconductor device of claim 19, wherein the electronic component includes a buried trench capacitor.

21. The semiconductor device of claim 19, wherein the second crystalline silicon layer includes a seed layer contacting the electronic component.

22. The semiconductor device of claim 19, further comprising a transistor extending into the second crystalline silicon layer.

23. A method, comprising:
depositing a semiconductor layer over a semiconductor crystal lattice having an oxide layer thereover; and
implanting group IV ions into the semiconductor layer and the semiconductor crystal lattice, wherein the semiconductor layer crystalizes by solid phase epitaxy to extend the semiconductor crystal lattice.

24. The method of claim 23, wherein the group IV ions comprise Si ions, Ge ions and/or a combination of both.

25. The method of claim 23, wherein the semiconductor layer is amorphous before the implanting and has a thickness of about 20 nm to 80 nm.

26. The method of claim 23, wherein the implanting includes implanting the group IV ions at a dosage and having an energy level that results in disrupting the oxide layer.
